(19) United States
(12) Patent Application Publication
(10) Pub. No.: US 2025/0239533 A1
(43) Pub. Date: Jul. 24, 2025

(54) SEMICONDUCTOR MODULE

(71) Applicant: TDK Corporation, Tokyo (JP)

(72) Inventors: Reo HANADA, Tokyo (JP); Kazutoshi TSUYUTANI, Tokyo (JP); Toshiyuki ABE, Tokyo (JP)

(21) Appl. No.: 19/009,171

(22) Filed: Jan. 3, 2025

(30) Foreign Application Priority Data
Jan. 18, 2024 (JP) 2024-005926

(51) Int. Cl. H01L 23/538; H01L 23/29; H01L 25/11

(52) U.S. Cl. CPC H01L 23/5386; H01L 23/295; H01L 23/5385; H01L 25/117

(57) ABSTRACT

Disclosed herein is a semiconductor module that includes a substrate body including first to third insulating layers, a semiconductor IC embedded in the first insulating layer, an external terminal provided on the first surface of the substrate body, a first via formed in the first and second insulating layers, a second via formed in the first and third insulating layers, a first via conductor embedded in the first via and connecting the terminal electrode of the first semiconductor IC and the first external terminal, a second via conductor embedded in the second via and connected to the back surface conductor of the first semiconductor IC, and a mold resin covering the second surface of the substrate body. The second via conductor has a conformal via structure having a recess without completely filling the second via. A part of the mold resin is filled in the recess.

### CROSS-REFERENCE TO RELATED APPLICATION

This application claims the benefit of Japanese Patent Application No. 2024-005926, filed on Jan. 18, 2024, the entire disclosure of which is incorporated by reference herein.

### BACKGROUND OF THE ART

### Field of the Art

The present disclosure relates to a semiconductor module.

### Description of Related Art

JP 2013-229548A discloses a semiconductor module having a semiconductor IC (Integrated Circuit) embedded in a substrate body with a multilayer structure.

Semiconductor modules of such a type sometimes require high heat dissipation performance when the semiconductor IC embedded in the substrate body is a device with a large heat generation amount, such as a power device.

### SUMMARY

The present disclosure describes a technology for enhancing, in a semiconductor module having a structure in which a semiconductor IC is embedded in a substrate body, heat dissipation performance of the semiconductor IC.

A semiconductor module according to an aspect of the present disclosure includes: a substrate body including a first insulating layer, a second insulating layer stacked on one surface of the first insulating layer, and a third insulating layer stacked on the other surface of the first insulating layer and having a first surface positioned on the second insulating layer side and a second surface positioned on the third insulating layer side; a first semiconductor IC embedded in the first insulating layer and having a main surface on which a terminal electrode is provided and a back surface positioned on a side opposite to the main surface and on at least a part of which a back surface conductor is formed; a first external terminal provided on the first surface of the substrate body; a first via formed in the first and second insulating layers; a second via formed in the first and third insulating layers; a first via conductor filled in the first via and connecting the terminal electrode of the first semiconductor IC and the first external terminal; a second via conductor filled in the second via and connected to the back surface conductor of the first semiconductor IC; and a mold resin covering the second surface of the substrate body. The second via conductor has a conformal via structure of forming a recess without completely filling the second via, and part of the mold resin is filled in the recess. This enhances adhesion between the substrate body and the mold resin.

### BRIEF DESCRIPTION OF THE DRAWINGS

The above features and advantages of the present disclosure will be more apparent from the following description of some embodiments taken in conjunction with the accompanying drawings, in which:

FIG. 1 is a schematic cross-sectional view illustrating the structure of a semiconductor module 100 according to an embodiment of the present disclosure;

FIG. 2A shows an example of an electrode pattern shape on the main surface 41 of the semiconductor IC 40;

FIG. 2B shows an example of a pattern shape of the redistribution layer W covering the main surface 41 of the semiconductor IC 40;

FIG. 2C shows an example of a pattern shape of the conductor layer L2; and

FIG. 3 is a schematic cross-sectional view illustrating the structure of a semiconductor module 100A according to a modification.

### DETAILED DESCRIPTION OF THE EMBODIMENTS

Some embodiments of the present disclosure will be explained below in detail with reference to the accompanying drawings.

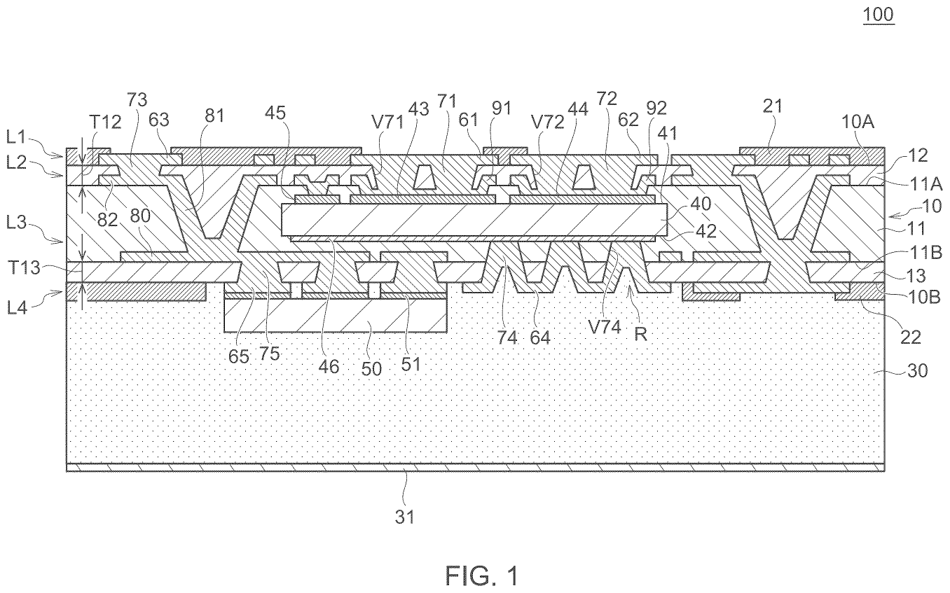

FIG. 1 is a schematic cross-sectional view illustrating the structure of a semiconductor module 100 according to an embodiment described herein.

The semiconductor module 100 illustrated in FIG. 1 includes a substrate body 10 having a structure in which insulating layers 11 to 13 are stacked and conductor layers L1 to L4 provided on the surface of or inside the substrate body 10. The insulating layer 11 is positioned at substantially the center of the thickness direction of the substrate body 10. The insulating layer 12 is formed on one surface 11A of the insulating layer 11, and the insulating layer 13 is formed on the other surface 11B thereof. The surface the insulating layer 12 constitutes one surface 10A of the substrate body 10. The surface of the insulating layer 13 constitutes the other surface 10B of the substrate body 10. The surface 10A of the substrate body 10 is partially covered with a solder resist 21. The surface 10B of the substrate body 10 is partially covered with a solder resist 22.

The insulating layer 12 may contain an inorganic filler such as silica. This enhances the strength of the insulating layer 12 and can reduce the thermal expansion coefficient of the insulating layer 12. The insulating layer 13 may contain glass cloth. This enhances the strength of the insulating layer 13 and can reduce the thermal expansion coefficient of the insulating layer 13. By contrast, the insulating layer 11 may not necessarily contain inorganic filler, glass cloth or the like. The thermal expansion coefficient of the insulating layer 12 may be higher than that of the insulating layer 13. A thickness T12 of the insulating layer 12 may be smaller than a thickness T13 of the insulating layer 13.

The conductor layer L1 is positioned on the surface 10A of the substrate body 10. The conductor layer L4 is positioned on the surface 10B of the substrate body 10. The conductor layer L2 is positioned between the insulating layers 11 and 12. The conductor layer L3 is positioned between the insulating layers 11 and 13.

A semiconductor IC 40 is embedded in the insulating layer 11. The semiconductor IC 40 may be an integrated circuit formed using various semiconductor materials. Specifically, for example, the semiconductor IC 40 may be a power device (device used for power conversion, power control, etc.) using GaN as a substrate material. A plurality of terminal electrodes 43 to 45 are provided on a main surface 41 of the semiconductor IC 40 that faces the insulating layer 12 side. When the semiconductor IC is a MOS power device, the terminal electrodes 43 to 45 may serve as a source electrode, a drain electrode, and a gate electrode, respectively. The terminal electrodes 43 to 45 may be formed of a redistribution layer provided on the main surface 41 of the semiconductor IC 40. A back surface 42 of the semiconductor IC 40 that is positioned on a side opposite to the main surface 41 and faces the insulating layer 13 side is covered with a back surface conductor 46 contributing to heat dissipation. The back surface 42 of the semiconductor IC 40 may be covered entirely or partially with the back surface conductor 46. A conductor constituting the back surface conductor 46 may be Cu or a laminate of Ti and Cu.

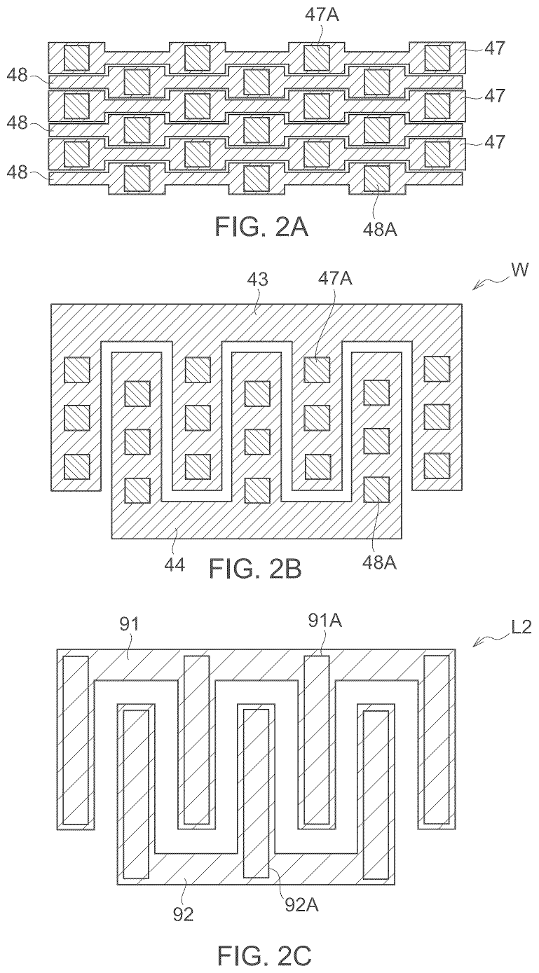

In the example illustrated in FIG. 2A, a plurality of source electrode patterns 47 and a plurality of drain electrode patterns 48 are alternately arranged on the main surface 41 of the semiconductor IC 40. In the example illustrated in FIG. 2B, a plurality of source electrode patterns 47 are connected to the plurality of terminal electrodes 43 positioned in a redistribution layer W through a plurality of via conductors 47A, and a plurality of drain electrode patterns 48 are connected to the terminal electrode 44 positioned in the redistribution layer W through a plurality of via conductors 48A. In the example illustrated in FIG. 2C, a wiring pattern 91 positioned in the conductor layer L2 is connected to the terminal electrode 43 through a plurality of via conductors 91A, and a wiring pattern 92 positioned in the conductor layer L2 is connected to the terminal electrode 44 through a plurality of via conductors 92A.

A conductor constituting the redistribution layer W may be a laminate of Cu, Ni, and Au. The thermal expansion coefficient of the redistribution layer W may be lower than that of the back surface conductor 46. In this case, the semiconductor IC 40 is more likely to be warped with a change in temperature.

A plurality of external terminals including external terminals 61 to 63 are provided in the conductor layer L1. The external terminals 61 to 63 are exposed from the surface 10A of the substrate body 10. In the example illustrated in FIG. 1, the external terminal 61 is connected to the terminal electrode 43 of the semiconductor IC 40 through a plurality of via conductors 71 and the wiring pattern 91, and the external terminal 62 is connected to the terminal electrode 44 of the semiconductor IC 40 through a plurality of via conductors 72 and the wiring pattern 92.

The via conductors 71 are each formed across the insulating layers 11 and 12 so as to be filled in a via V71 exposing therethrough the wiring pattern 91, whereby the terminal electrode 43 of the semiconductor IC 40 and the external terminal 61 are electrically connected to each other. The via conductors 72 are each formed across the insulating layers 11 and 12 so as to be filled in a via V72 exposing therethrough the wiring pattern 92, whereby the terminal electrode 44 of the semiconductor IC 40 and the external terminal 62 are electrically connected to each other. The wiring patterns 91 and 92 need not necessarily be provided, and the via conductors 71 and 72 may be connected directly to the terminal electrodes 43 and 44, respectively. As described above, since the external terminals 61 and 62 are respectively disposed immediately above the terminal electrodes 43 and 44 and connected thereto through the respective via conductors 71 and 72, resistance values between the terminal electrode 43 and the external terminal 61 and between the terminal electrode 44 and the external terminal 62 are reduced. In addition, the terminal electrode 43 (44) and external terminal 61 (62) are connected to each other through the plurality of via conductors 71 (72), so that a resistance value therebetween is further reduced.

When the semiconductor IC 40 is a power device, a large current flows in the terminal electrodes 43, 44, via conductors 71, 72, and external terminals 61, 62, so that the insulating layer 12 for insulation therebetween needs to have high insulating performance. By using an inorganic filler-containing resin containing no glass cloth as the insulating layer 12, insulating performance is improved as compared with when using the insulating layer 12 containing glass cloth. Further, when the insulating layer 12 contains an inorganic filler, migration is less likely to occur as compared with the case where it contains glass cloth, making it possible to achieve high reliability.

A plurality f vias V74 extending across the insulating layers 11 and 13 so as to expose therethrough the back surface conductor 46 are formed at positions overlapping the back surface conductor 46 provided to the semiconductor IC 40. The vias V74 are each filled with a via conductor 74 connected to the back surface conductor 46, and the back surface conductor 46 is connected, through this via conductor 74, to a conductor pattern 64 provided in the conductor layer L4 and contributing to heat dissipation. The conductor pattern 64 may be applied with a ground potential. The conductor layer L4 has a plurality of external terminals 65 in addition to the conductor pattern 64. The conductor pattern 64 and external terminals 65 are exposed from the surface 10B of the substrate body 10.

A semiconductor IC 50 having a plurality of terminal electrodes 51 is mounted on the surface 10B of the substrate body 10. The semiconductor IC 50 is mounted on the surface 10B of the semiconductor body 10 such that the terminal electrodes 51 and external terminals 65 are electrically connected to each other. When the semiconductor IC 40 embedded in the insulating layer 11 is a power device, the semiconductor IC 50 may include a driver circuit for driving the semiconductor IC 40. A wiring pattern for supplying a ground potential to the semiconductor IC 50 may be electrically isolated from the back surface conductor 46. The semiconductor IC 50 may be mounted at a position overlapping the semiconductor IC 40 in a plan view. This can reduce the length of a wiring for connecting the semiconductor ICs 40 and 50 and reduce the planar size of the entire semiconductor module 100.

In the example illustrated in FIG. 1, one of the external terminals 65 is connected, through a via conductor 75 penetrating the insulating layer 13, to a wiring pattern 80 positioned in the conductor layer L3. The wiring pattern 80 is connected, through a via conductor 81 penetrating the insulating layer 12, to a wiring pattern 82 positioned in the conductor layer L2. The wiring pattern 82 is connected, through via conductor 73 penetrating the insulating layer 11, to the external terminal 63 positioned in the conductor layer L1.

The semiconductor module 100 according to the present embodiment further includes a mold resin 30 that covers the surface 10B of the substrate body 10. The mold resin embeds therein the semiconductor IC 50 and contacts the conductor pattern 64. The mold resin 30 enhances the strength of the entire semiconductor module 100, protects the semiconductor IC 50, and functions as a member that dissipates heat generated from the semiconductor IC 40. The mold resin 30 may contain a filler for enhancing thermal conductivity. Further, the outer surface of the mold resin 30 may be covered with a metal layer 31 for enhancing heat dissipation performance.

In the example illustrated in FIG. 1, the via conductors 71 and 72 have a f filled-via structure (a structure in which a via is filled up with a conductor), while the via conductor 74 has a conformal via structure (a structure in which a via is not completely filled up to form a recess R). When the via conductors 71 and 72 have the filled-via structure, a resistance value between the semiconductor IC 40 and the external terminals 61 and 62 is reduced, and heat dissipation performance through the external terminals 61 and 62 is enhanced. The via conductors 73 and 75 may also have the filled-via structure.

Since the via conductor 74 has the conformal via structure, a part of the mold resin 30 is filled in the recess R formed thereby. As a result, peeling at the interfaces between the conductor pattern 64 and the mold resin 30 and between the via conductor 74 and the mold resin 30 becomes unlikely to occur due to anchor effect. That is, when the recess R is absent, a flat conductor pattern 64 contacts the mold resin 30, so that peeling at the interface therebetween becomes likely to occur if a temperature change is repeated. However, in the present embodiment, a part of the mold resin 30 is filled in the recess R formed by the via conductor 74, so that, peeling at the interface therebetween becomes unlikely to occur even with repetition of a temperature change.

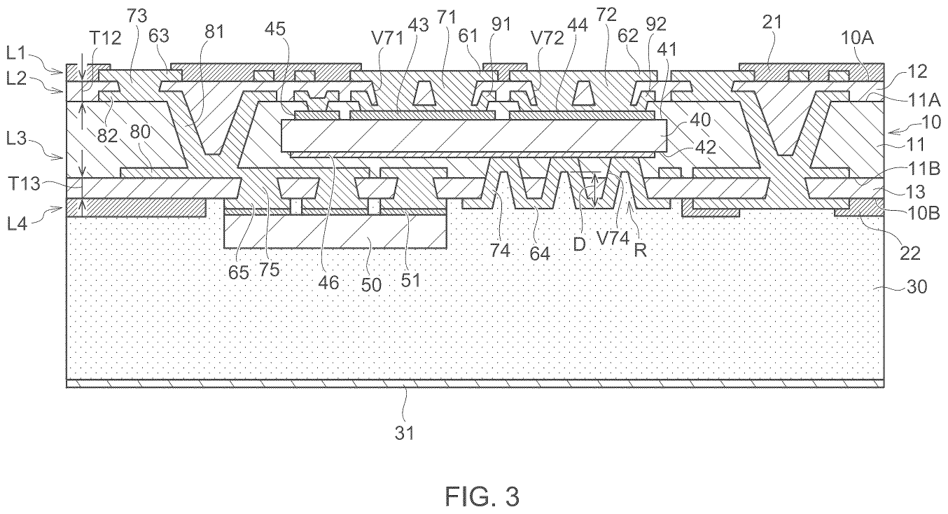

FIG. 3 is a cross-sectional view of a semiconductor module 100A according to a modification, which illustrates a configuration for enhancing the adhesion of the mold resin 30. As illustrated, the shape of the via conductor 74 may be controlled such that a depth D of the recess R is larger than a thickness T13 of the insulating layer 13. Further, when the mold resin 30 contains a filler, the filler density of the mold resin 30 may become locally low in the recess R. This further enhances adhesion between the mold resin 30 and the via conductor 74. The filler density in the recess R can be controlled by, for example, the particle diameter of the filler added to the mold resin 30.

As described above, in the semiconductor module 100 according to the present embodiment, the surface 10B of the substrate body 10 is covered with the mold resin 30. The mold resin 30 contacts the conductor pattern 64 and via conductor 74, and the via conductor 74 is connected to the back surface conductor 46 of the semiconductor IC 40, allowing heat generated from the semiconductor module 100 to be dissipated efficiently to the mold resin 30 side. In addition, the via conductor 74 has the conformal via structure, and a part of the mold resin 30 is filled in the recess R formed thereby, with the result that peeling of the mold resin 30 due to repetition of a temperature change becomes less likely to occur.

The via conductors 71 and 72 connected to the semiconductor IC 40 and the via conductor 75 connected to the semiconductor IC 50 have the filled-via structure, thus achieving high conductivity and high heat dissipation performance. Further, the insulating layer 11 embedding therein the semiconductor IC 40 is larger in thickness than the insulating layers 12 and 13, and the via conductor 81 penetrating the insulating layer 11 may have the conformal via structure.

When the thermal expansion coefficient of the redistribution layer W is smaller than that of the back surface conductor 46, the semiconductor IC 40 is more likely to be warped with a change in temperature. However, when the thermal expansion coefficient of the insulating layer 12 positioned on the redistribution layer W side is larger than that of the insulating layer 13 positioned on the back surface conductor 46 side, stress occurring in the semiconductor IC 40 due to a difference in thermal expansion coefficient between the redistribution layer W and the back surface conductor 46 is canceled, whereby the warpage of the semiconductor IC 40 can be prevented.

When the difference in thermal expansion coefficient between the redistribution layer W and the back surface conductor 46 is not so large, stress caused due to the difference in thermal expansion coefficient between the insulating layers 12 and 13 may sometimes be larger than stress caused due to the difference in thermal expansion coefficient between the redistribution layer W and the back surface conductor 46. In this case, the stress caused due to the difference in thermal expansion coefficient between the redistribution layer W and the back surface conductor 46 is excessively canceled by the stress caused due to the difference in thermal expansion coefficient between the insulating layers 12 and 13. That is, when the difference in thermal expansion coefficient between the insulating layers 12 and 13 is larger than that between the redistribution layer W and the back surface conductor 46, the semiconductor IC 40 may be warped in the opposite direction due to excessive cancellation of the stress. In such a case, the thickness T12 of the insulating layer 12 may be made smaller than the thickness T13 of the insulating layer 13 to reduce the impact of stress caused due to the difference in thermal expansion coefficient between the insulating layers 12 and 13.

Further, the influence of the difference in thermal expansion coefficient between the insulating layers 12 and 13 may be reduced by making the area of the wiring patterns included in the conductor layers L1 and L2 which are positioned on the insulating layer 12 side with respect to the insulating layer 11 larger than the area of the wiring patterns included in the conductor layers L3 and L4 which are positioned on the insulating layer 13 side with respect to the insulating layer 11. In other words, an increase in the area of the wiring patterns included in the conductor layers L1 and L2 reduces the entire thermal expansion coefficient of the conductor layers L1, L2 and insulating layer 12. This can adjust the difference from the entire thermal expansion coefficient of the conductor layers L3, L4 and insulating layer 13, making it possible to prevent warpage of the semiconductor IC 40.

While the embodiment of the technology according to the present disclosure has been described, the technology according to the present disclosure is not limited to the above embodiment, and various modifications may be made within the scope of the present disclosure, and all such modifications are included in the technology according to the present disclosure.

Although a semiconductor IC (semiconductor IC 40) having terminal electrodes (terminal electrodes 43 to 45) on its main surface (main surface 41) is exemplified in the above-described embodiment, the technology according to the present disclosure is also applicable to semiconductor ICs having other configurations. For example, the technology according to the present disclosure may be applicable to a semiconductor IC having a terminal electrode on its back surface side and further to a semiconductor IC having another element, such as a wiring pattern, in addition to the terminal electrodes on its main surface.

The technology according to the present disclosure includes the following configuration examples, but not limited thereto.

A semiconductor module according to an aspect of the present disclosure includes: a substrate body including a first insulating layer, a second insulating layer stacked on one surface of the first insulating layer, and a third insulating layer stacked on the other surface of the first insulating layer and having a first surface positioned on the second insulating layer side and a second surface positioned on the third insulating layer side; a first semiconductor IC embedded in the first insulating layer and having a main surface on which a terminal electrode is provided and a back surface positioned on a side opposite to the main surface and on at least a part of which a back surface conductor is formed; a first external terminal provided on the first surface of the substrate body; a first via formed in the first and second insulating layers; a second via formed in the first and third insulating layers; a first via conductor filled in the first via and connecting the terminal electrode of the first semiconductor IC and the first external terminal; a second via conductor filled in the second via and connected to the back surface conductor of the first semiconductor IC; and a mold resin covering the second surface of the substrate body. The second via conductor has a conformal via structure of forming a recess without completely filling the second via, and part of the mold resin is filled in the recess. This enhances adhesion between the substrate body and the mold resin.

In the above semiconductor module, the first via conductor may have a filled-via structure in which the first via is filled up with a conductor. This reduces the resistance value of the first via conductor and enhances heat dissipation performance through the first via conductor.

In the above semiconductor module, the first semiconductor IC may be a power device. Thus, heat generated from the first semiconductor IC as the power device can be dissipated efficiently.

The above semiconductor module may further include a second external terminal provided on the second surface of the substrate body and a second semiconductor IC mounted on the second surface of the substrate body so as to be connected to the second external terminal, the second semiconductor IC may include a driver circuit for driving the first semiconductor IC, and the second semiconductor IC may be disposed at a position partially overlapping the first semiconductor IC in a plan view in the stacking direction and may be embedded in the mold resin. This can reduce the planar size of the substrate body and can protect the second semiconductor IC using the mold resin.

In the above semiconductor module, the depth of the recess may be larger than the thickness of the third insulating layer. This further enhances adhesion between the substrate body and the mold resin.

The above semiconductor module may further include a metal layer that covers the outer surface of the mold resin. This further enhances heat dissipation performance through the mold resin.

In the above semiconductor module, the mold resin may contain a filler, and the filler density of the mold resin may become locally low in the recess. This still further enhances adhesion between the substrate body and the mold resin.

What is claimed is:

1. A semiconductor module comprising:
a substrate body including a first insulating layer, a second insulating layer stacked on one surface of the first insulating layer, and a third insulating layer stacked on another surface of the first insulating layer, the substrate body having a first surface positioned on the second insulating layer side and a second surface positioned on the third insulating layer side;
a first semiconductor IC embedded in the first insulating layer, the first semiconductor IC having a main surface on which a terminal electrode is provided and a back surface positioned on a side opposite to the main surface, at least a part of the back surface of the first semiconductor IC being covered with a back surface conductor;
a first external terminal provided on the first surface of the substrate body;
a first via formed in the first and second insulating layers;
a second via formed in the first and third insulating layers;
a first via conductor embedded in the first via and connecting the terminal electrode of the first semiconductor IC and the first external terminal;
a second via conductor embedded in the second via and connected to the back surface conductor of the first semiconductor IC; and
a mold resin covering the second surface of the substrate body,
wherein the second via conductor has a conformal via structure having a recess without completely filling the second via, and
wherein a part of the mold resin is filled in the recess.

2. The semiconductor module as claimed in claim 1, wherein the first via conductor has a filled-via structure in which the first via is filled up with a conductor.

3. The semiconductor module as claimed in claim 1, wherein the first semiconductor IC is a power device.

4. The semiconductor module as claimed in claim 3, further comprising:
a second external terminal provided on the second surface of the substrate body; and
a second semiconductor IC mounted on the second surface of the substrate body so as to be connected to the second external terminal,
wherein the second semiconductor IC includes a driver circuit for driving the first semiconductor IC, and
wherein the second semiconductor IC is embedded in the mold resin so as to partially e first semiconductor IC in a plan view.

5. The semiconductor module as claimed in claim 1, wherein a depth of the recess is larger than a thickness of the third insulating layer.

6. The semiconductor module as claimed in claim 1, further comprising a metal layer that covers an outer surface of the mold resin.

7. The semiconductor module as claimed in claim 1,
wherein the mold resin contains a filler, and
wherein a filler density of the mold resin becomes locally low in the recess.
